(19) United States
(12) Patent Application Publication
(10) Pub. No.: US 2007/0095283 A1
(43) Pub. Date: May 3, 2007

(54) Pumping System for Atomic Layer Deposition

(76) Inventor: Carl Johan Galewski, Santa Cruz, CA (US)

Correspondence Address: CENTRAL COAST PATENT AGENCY, INC, 3 HANGAR WAY SUITE D, WATSONVILLE, CA, 95076, US

(21) Appl. No.: 11/553,239

(22) Filed: Oct. 26, 2006

Related U.S. Application Data
(60) Provisional application No. 60/732,428, filed on Oct. 31, 2005.

(51) Int. Cl. F17D 1/00; H01L 21/306; C23C 16/00

(52) U.S. Cl. 118/715; 156/345.29; 137/1

(57) ABSTRACT

A pumping apparatus for evacuating a reactant from a reactive region includes a vacuum able chamber, a hearth for supporting a workpiece, one or more gas introduction valves, one or more exhaust evacuation valves, and an adjustable valve providing one or more pathways there through formed by alignment of separate components of the valve, the components perforated with two or more openings to form the pathways.

### CROSS-REFERENCE TO RELATED APPLICATIONS

The present invention claims priority to a U.S. provisional patent application Ser. No. 60/732,428 filed on Oct. 31, 2005 entitled “ALD Pumping System” which is included herein at least by reference.

### BACKGROUND OF THE INVENTION

1. Field of the Invention

The present invention is in the field of semiconductor manufacturing equipment used in chemical vapor deposition (CVD) processes including a category of CVD known as Atomic Layer Deposition (ALD). The invention pertains particularly to methods and apparatus for regulating and manipulating purge exhaust pumping steps between reactive vapor deposition steps.

2. Discussion of the State of the Art

ALD processing encompasses one or more time-separated pulses of gas reactants, typically including but not limited to reactive gases, that react with a surface treatment of a work piece to provide deposition of a thin film of material resultant of the reaction. Usually gas phase reactants and sub-atmospheric pressure are used to form thin films on substrates heated to a moderate temperature of 100 to 400° C. In the material deposition of one or more substrates, small increases of the thin film material produced from the reactive substances accumulate over subsequent deposition cycles building up to a final film thickness over a number of cycles.

Therefore, in CVD processing and particularly with ALD processing, the importance of quickly cycling gasses in and out of the reactive area of the processing chamber is well known. Likewise, it is also desired that there is little or no reaction of gasses in the gas exhaust region beyond the reactive region.

In typical practice, the best chemistries known for creating thin films in ALD processing, for example, include reactive components that react very strongly. When mixed in gas phase, those components react violently and without adequate controls can form undesired deposits and/or particles deposited directly out of the gas phase. In some cases these deposits and/or particles can debilitate or destroy a vacuum pumping system. Therefore, it is extremely important particularly with ALD, to fully remove a first reactant before introducing the next reactant into a reactive region. Likewise, as mentioned further above it is important to ensure that reaction is suppressed, or even completely eliminated in the exhaust region.

In ALD, a very small amount of reactant gas may be utilized per deposition cycle. For example, a single dose of reactant required to coat a 300 mm diameter semiconductor wafer with one layer of molecules may be as small as 0.02 std cc. (One mole of gas occupies 22.4 liters at a standard chamber condition of 0 degrees Celsius and 1 atm.) Given that reactor volumes are typically on the order of liters, it is not uncommon for an ALD process to operate at less than 1% efficiency rate. This introduces another problem in that the inefficient use of a gas reactant is not only costly but also increases the possibility of undesired reaction in the exhaust from the chamber. This inefficiency factor contributes to increased maintenance, not withstanding risk to vacuum pumps and elevated “scrubbing” requirements before exhaust can be released to atmosphere.

Most efficient use of ALD, in particular, involves a dosing step and a purge step for each single reactive cycle under different conditions. In most cases, a dosing should entail a low gas flow, a longer residence time, and maximum precursor concentration. A purging step should entail a higher gas flow, a shorter residence time to most quickly achieve a minimum residual precursor concentration. Depending partly on the application and the chemistry being used, ALD may require dose and purge steps on the order of 100 milliseconds or less. Cycling a physical mass at those speeds is challenging by itself. The faster the mass needs to move, the lower the mass has to be to equate to success.

A typical approach is to utilize small valves that have been developed and that can respond in 5 ms. Such valves are commonly used for controlling the injection of reactants and purge gas. However, moving a larger device that can regulate a large cross-section separating a reactive and an exhaust region in an ALD apparatus can be much more challenging. Use of gas injected by small valves and flow restrictors has been proposed, but may suffer from being difficult to set up and operate consistently over time. Configurations using some form of exhaust constriction by mechanical means have also been proposed. However, implementation of these mechanical means as suggested may actually increase formation of particles from physical contact between moving members or increased opportunity for unwanted reactions in the exhaust region.

What is clearly needed in the art is an apparatus and method for varying pumping speeds in real time to accomplish more desirable results, increasing efficiency while also lowering particulate contaminants and/or undesired deposits in both the reactive region as well as in the exhaust region.

### SUMMARY OF THE INVENTION

A pumping apparatus is provided for evacuating a reactant from a reactive region. The pumping apparatus includes a vacuum able chamber, a hearth for supporting a workpiece, one or more gas introduction valves, one or more exhaust evacuation valves, and an adjustable valve providing one or more pathways there through formed by alignment of separate components of the valve, the components containing two or more openings to form the pathways. In one embodiment, the pumping apparatus is used in atomic layer deposition. In another embodiment, the pumping apparatus is used in chemical vapor deposition.

In one embodiment, the valve components are annular plates arranged one above the other and wherein one of those plates may be rotated to form or to block the pathways. In this embodiment, the plate that is not rotated is permanently affixed to the chamber and to a centrally located hearth. In one embodiment, magnetic coupling from outside the chamber controls the rotably adjustable plate. In another embodiment, a centrally located spindle controls the rotably adjustable plate.

In one embodiment, the chamber includes one reactive region located above the adjustable valve, and one exhaust region located below the adjustable valve. In another embodiment, the chamber includes one reactive region located above the adjustable valve, and two or more isolated exhaust regions located below the adjustable valve, the exhaust regions isolated from one another by the rotated position of the rotably adjustable plate of the valve. In one embodiment using a spindle, the spindle is magnetically coupled to the rotably adjustable plate. In a variation of this embodiment, the spindle is physically attached to the rotably adjustable plate.

According to another aspect of the invention, an adjustable valve is provided for evacuating a reactive precursor from a reactive region in a semiconductor thin film process chamber. The adjustable valve includes a first perforated component rendered stationary within the process chamber, and a second perforated component geometrically similar to the first perforated component, the second perforated component rotable within the chamber to align one or more of the perforations common to both components to form one or more pathways through the valve and rotable within the chamber to misalign all of the perforations common to both components to prevent pathways through the valve.

In one embodiment, the semiconductor thin film process is an atomic layer deposition process. Also in one embodiment, the first and second perforated components are annular plates. In a variation of this embodiment, the second perforated component is adjustable using magnetic coupling. In another variation of this embodiment, the first perforated component is contiguously formed with the process chamber. In one embodiment, both perforated components have identical perforations strategically located in identical patterns.

According to a further aspect of the present invention a method is provided for purging a reactant from a reactive region of a semiconductor thin film process using an adjustable valve adjacent to the reactive region, the valve including a first perforated component rendered stationary within a process chamber, and an adjustable second perforated component geometrically similar to the first perforated component. The method includes the acts (a) determining that a reaction has occurred in the reactive region, and (b) adjusting the second perforated component to align one or more perforations common to both perforated components, the adjustment performed under vacuum pressure.

In one aspect of the method in act (a), the determination is made according to the passing of a pre-planned time window in which the reaction is expected to have occurred and completed. In one aspect of the method in act (b), the perforated components are annular plates and the adjustment is a rotation of one of the plates.

In one aspect n in act (a), sensors indicating the actual position of the adjustable valve are provided and control the actuation of gas introduction valves used for reactant and purge gas injection in act (b).

### BRIEF DESCRIPTION OF THE DRAWING FIGURES

FIG. 1 is an elevation section view of an atomic layer deposition apparatus according to an embodiment of the present invention.

FIG. 2 is a plan view of a vacuum evacuation plate valve according to an embodiment of the present invention.

FIG. 3 is an elevation section view of an atomic layer deposition apparatus according to another embodiment of the present invention.

FIG. 4 is a process flow chart illustrating acts for purging reactants into a single exhaust region according to an embodiment of the present invention.

FIG. 5 is a process flow chart illustrating acts for purging reactants into alternate exhaust regions according to an embodiment of the present invention.

### DETAILED DESCRIPTION

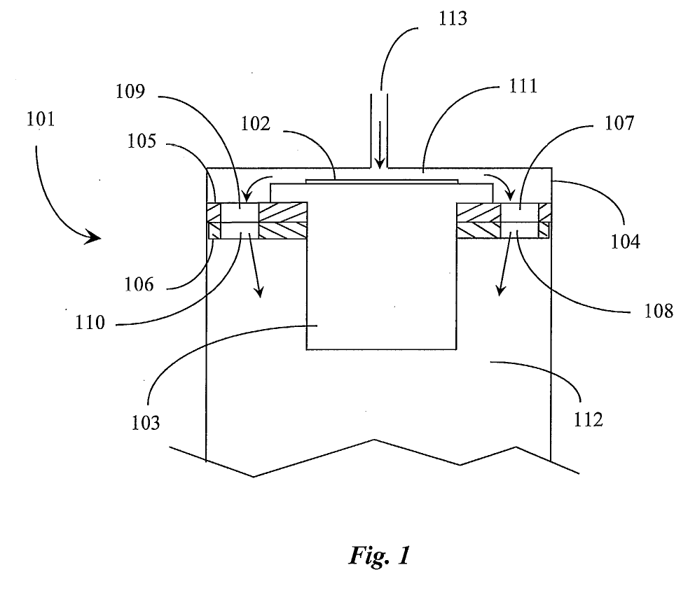

FIG. 1 is an elevation section view of an atomic layer deposition apparatus according to an embodiment of the present invention. Atomic Layer Deposition (ALD) apparatus 101 is logically illustrated in this example as representative of a typical ALD processing environment including a stationary hearth and frame structure 103 that supports a workpiece 102 that will be developed with thin films. Hearth 103 and workpiece 102 are, during processing, enclosed in a vacuum-tight ALD chamber 104 as is typical in the art. Workpieces 102 may be a silicon wafer or a wide variety of other types of workpieces that may be coated.

Chamber 104 may be provided in aluminum, stainless steel, or any other durable material known to be applicable in ALD processing. Workpiece 102 is assumed to be pre-treated with an agent that will react with an introduced reactive gas. Chamber 104 has an input valve 113, through which gasses are introduced into a process region, also called a reactive region 111. Introduction valve 113 is exemplary only. There may be other locations for introduction valves on chamber 104, as well as more than one valve without departing from the spirit and scope of the present invention.

In this example, reactive precursors are introduced through valve 113 into reactive region 111 in the direction of the arrow shown. Reactive region 111 is generally defined as the space closest to the workpiece where the introduced precursor reacts with the material on the surface of the workpiece to produce a layer of thin film.

A pair of annular valve plates illustrated herein as a valve plate 105 and a valve plate 106 further defines reactive region 111. Valve plates 105 and 106 together form a vacuum valve for enabling very quick high-flow purging of any gas reactant from reactive region 111 after a cycle of reaction has occurred. The precursor gasses introduced, typically one at a time, flow radially out over workpiece 102 with the plate-valve typically closed during the reaction phase of each ALD cycle.

Plate 105 and 106 are not identical plates. One plate, plate 105 in this example, is welded, contiguously formed with or otherwise intimately attached around its outer diameter to the inside wall of chamber 104 such that gasses are restricted from passing around the periphery of the plate. In one embodiment, plate 105 has an inner diameter just large enough to fit over the outer diameter of the main body of hearth 103. Plate 105 may also be permanently affixed by welding, contiguously formed with or otherwise intimately attached to the outer wall of hearth 103 such that gasses are restricted from passing by the inner wall of the plate. In this example, plate 105 is fixed in ALD apparatus 101 and cannot be moved, adjusted or rotated. In one embodiment, plate 105 is fixed to chamber 104 and hearth 103 such that there is no gap between the plates outer and inner diameters and the interfacing walls of the chamber and hearth. In one embodiment, plate 105 is a contiguous part of chamber 104 and is not a separate piece that must be attached. In this embodiment, plate 105 is created along with chamber 104 when it is machined.

Plate 106, unlike plate 105, is not fixed to apparatus 101, and maybe adjusted rotably about hearth 103 in either direction. Plate 106 has an outer diameter just smaller that the inner diameter of chamber 104 and an inner diameter just larger than the outer diameter of the main body of hearth 103. The gap between the outer diameter of plate 106 and the chamber wall and the gap between inner diameter of plate 106 and the hearth main body are not as important as the gap spacing between plates 105 and 106 for determining the leakage of the overall valve structure. However, because of the simple geometry of the valve structure commonly used machining techniques can hold gaps within a range of about 20 to 50 microns if so required. Plates 105 and 106 have a very small gap between them just enough to enable rotation of one plate in geometric relation to the other without binding the plates or creating undesired contact or friction. In one embodiment, each plate on its interfacing surface has a pattern of concentric micro-rings machined therein such that one pattern is raised and the other is grooved. In this case, the plates may be brought very close together without touching while eliminating any gap between them by virtue of mating the patterns. In one embodiment, plate 105 may be the rotatable plate and plate 106 may be the fixed plate. However, the inventor prefers the rotate able plate to be on the bottom so that reactants cannot seep through to the lower plate unless it is rotated to an open position. However, it is not absolutely necessary to have a completely vacuum tight reactive region in order to practice the present invention successfully. In particular, a non-sealing valve such as implemented by plates 105 and 106 can be instrumental in preventing particles from both physical contact and unwanted reaction. Incorporating additional features such as grooves, narrowed passages, and possibly introduction of local purge gas in the gap between 105 and 106 all can effectively route each reactant towards separated locations and thereby suppress unwanted reaction.

Plates 105 and 106 may be manufactured of aluminum or stainless steel or other acceptable materials used in ALD processes. Typically such materials may be machined to a high state of finish and may maintain in a high degree of flatness and dimensional integrity through repeated ALD processing, which may exhibit temperature and pressure fluctuations.

In this example, plates 105 and 106 are perforated with a pattern of openings provided for enabling evacuation of precursor from reactive region 111 via vacuum exhaust pumping. In one embodiment, each pattern of openings may be identical for each plate. In another embodiment, one plate may have more openings than another plate. The exact number and profile of individual openings as well as strategic patterning of those openings, if any is observed, is a matter of design. As with many vapor deposition processes, shapes and sizes of openings provided for gas injection and evacuation may very, sometimes specifically, according to the types of chemistries used in the process. A general goal for reactive chemistries is to provide very low flows for dosing a reactive region in deposition and very high flows for purging the reactive region.

In this example, there are two fully bound elongated slots in each plate with both patterns identical to the other. It is noted herein that the openings do not have to be fully bound in order to practice the invention. For example, the openings may be slots that open to the outside wall of the plate. Plate 105 has openings 107 and 109 and plate 106 has openings 108 and 110. In this example, plate 106 may be rotated against plate 105 to align the openings forming pathways through the valve or to close off the openings blocking all potential pathways. Plates 105 and 106 together form a vacuum assisted evacuation valve for quick evacuation of any reactants left over from a deposition cycle.

Apparatus 101 has an exhaust region 112 that generally includes the region below plates 105 and 106. Apparatus 101 is pumped down using one or more vacuum pumps (not illustrated) or other mechanisms that can produce the vacuum required by the process. When plates 105 and 106 are aligned with respect to common perforations or openings, gas previously introduced into work region 111 may be quickly pumped out by exhaust region 112. A simple rotation of plate 106 in this example causes immediate evacuation of the gas through the aligned openings. One or more of the perforations in the plates are aligned, and the flow from region 111 to region 112 is very high and pressure very low providing optimum conditions needed for a purge step in the deposition cycle. When plates 105 and 106 are not aligned all of the openings are blocked. In this state there is little or no flow from region 111 into region 112. The pumping speed out of reactive region 111 is reduced or stopped entirely so that low flows and high pressure can be used to most efficiently utilize reactants during the dose step or reactive phase of the deposition cycle. This state is held for the required time of the reaction to form a layer of thin film on the work piece.

The mechanism and apparatus for powering the rotation of plate 106 is not illustrated in this example, but may be assumed present. In one embodiment, rotation of plate 106 may be accomplished through a magnetic coupling interface that may be mounted on the outside chamber 104 such that a magnetic interface makes contact with a similar interface provided on plate 106. Plate 106 may be controlled relative to rotation by automated computer-aided system in terms of rotation direction, amount of rotation, and frequency of rotation. The mechanics of controlling the rotation via magnetic coupling may be electronic, pneumatic, or compressed air assisted. At typical cycle speeds of 100 milliseconds or less for a complete dose and purge, one with skill in the art will appreciate that a purge valve such as the valve of this invention comprising plates 105 and 106 is much easier to move than a linearly activated vacuum plate typical of current practice. Moreover, the plate thickness required of linear plates under the typical vacuum conditions reached in chamber 104 is much higher, up to two times the required thickness of plate 106. Therefore faster dose and purge sequences are possible using the apparatus of the present invention.

In another embodiment, plate 106 may be controlled through a vertical spindle apparatus (not illustrated) that extends from the bottom-sealing surface of chamber 104 up through hearth 103 to the level of plate 106. In this case, magnetic coupling may also be implemented inside chamber 105 between the spindle and the inner diameter of plate 106, coupling accomplished through the wall of hearth 103. In a variation of this embodiment, there may be one or more a mechanical arms extending from the spindle through slots strategically placed through the wall of hearth 103 those arms connected to the inside wall of plate 106. Controlled rotation of the spindle then rotates the plate as required. In this embodiment, rotation amounts may be indexed and there may be continuing revolutions of plate 106 in one direction, or there may be back and forth rotations of a specific distance for aligning and blocking the openings. Control of the spindle may be electronic pneumatic or compressed air indexed. There are many possible physical manifestations that may be implemented using existing technologies that will not interrupt vacuum inside chamber 104 or otherwise interfere with the mechanics of the overall processing.

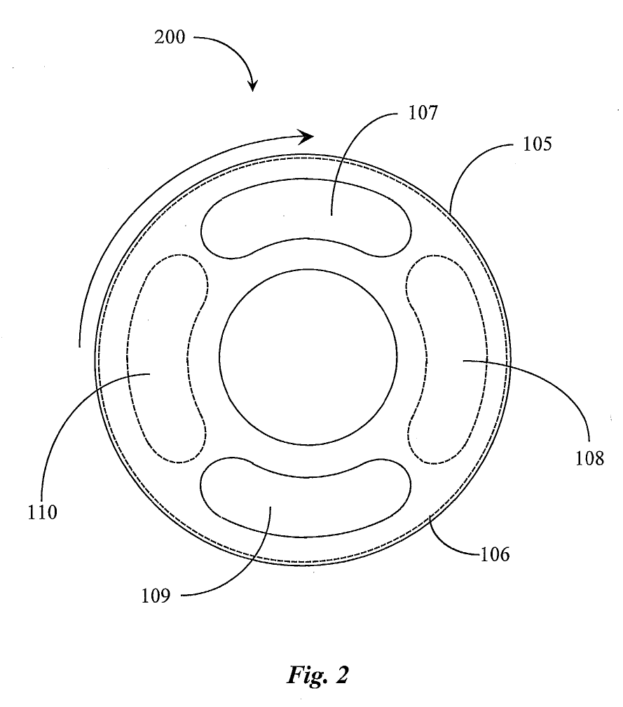

FIG. 2 is a plan view of a vacuum evacuation plate valve 200 according to an embodiment of the present invention. In this example, Plates 105 and 106 described above form valve 200. Either plate 105 or plate 106 may be the rotably adjustable plate in valve 200, but it is generally preferred that the bottom plate is the rotably adjustable plate for flow restriction purposes in this embodiment. In this example, openings 107 and 109 of plate 105 are not in alignment with openings 108 and 110 of plate 106. In this example, a 90 degree back and forth rotation of plate 106 can open and close valve 200. In one embodiment, there may be other planned amounts of rotation such as to partially align the perforations common to plates 105 and 106 to provide smaller or larger pathways if required. The flow speed variability is not limited and desired flow speeds depend on planned process chemistries used and required dose and purge cycle times associated to those chemistries. There are many possibilities.

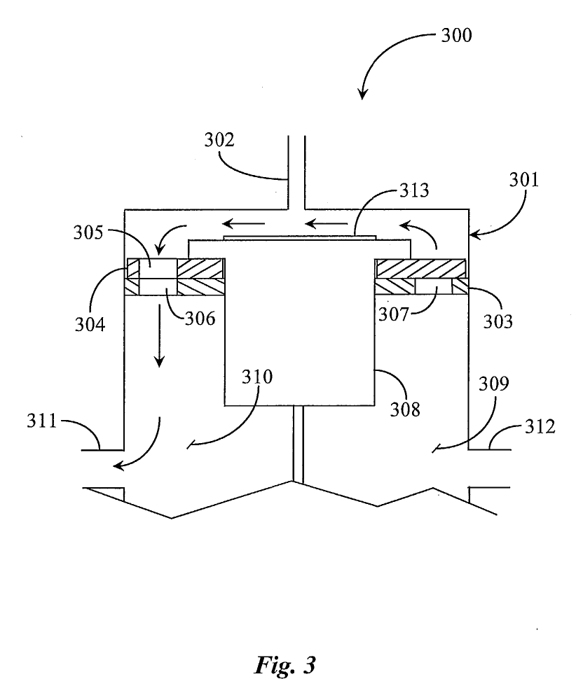

FIG. 3 is an elevation section view of an atomic layer deposition apparatus 300 according to another embodiment of the present invention. Apparatus 300 is very similar in conceptual design to apparatus 100 described above, with an exception that apparatus 300 is capable of alternating purge cycles such that gases may be pumped into two or more separated exhaust regions. In this example, a chamber 301 is illustrated and is logically separated into two different isolated exhaust regions. These exhaust regions are exhaust region 309 and exhaust region 310. As described further above with chamber 104, reactive gasses are introduced into chamber 300 through a central valve 302. A work piece 313 supported by a central hearth 308 is analogous to work piece 102 supported by hearth 103 described above.

In this example, a plate 304 and a plate 303 accomplish the valve of the present invention. In this example, plate 304 is the rotably adjustable plate and plate 303 is the fixed plate although the configuration may be reversed without departing from the spirit and scope of the present invention as was described further above. Fixed plate 303 has two openings illustrated here as opening 306 and opening 307. In this example, the openings are located approximately on opposite sides of the plate, one at zero degrees and the other at approximately 180 degrees. Openings 306 and 307 may be analogous in shape and size to openings 107 and 109 described further above. Other shapes and sizes as well as numbers and locations of openings may also be provided without departing from the spirit and scope of the present invention. The configuration shown here is exemplary only.

Unlike plate 303 that has two openings (one for each exhaust region) plate 304 may have a single opening or more openings. One opening visible in this example is opening 305. Opening 305 is positioned in alignment with opening 306 through plate 303. If there is a second opening in plate 304, it is not visible in this example because it is positioned behind hearth 308, perhaps at 90 degrees approximate from opening 305. In one embodiment, opening 305 is the only opening in plate 304. For exemplary purposes only, vacuum pump-out valves 311 and 312 are illustrated in this example. Valve 311 is dedicated to pump out exhaust region 310 and valve 312 is dedicated to pump out exhaust region 309.

In this particular configuration, it may be important that reactive gasses are purged into separate exhaust regions to, for example, allow for separated abatement treatment or routing to independent vacuum pumping system. For example in a first dose step a first reactive gas may be introduced into a reactive region or work region illustrated here as reactive region 314 through valve 302. After the reaction occurs in the dose step, plate 304 is rotated as shown here to align openings 305 and 306. In this case, the gas is pumped out through a pathway formed by openings 305 and 306 into exhaust region 310 and out through pump-out valve 311. In this case there is a high flow and low pressure with respect to exhaust region 310. The reactive gas is pumped out generally in the direction of the arrows.

For the next cycle, a different gas may be used. Plate 304 is rotated to block all openings for the dose of the next reactant. Low flows and high pressure occupy reactive region 314 for the dose step. Plate 304 may then be rotated to align opening 305 with opening 307 to form a pathway for purge of reactant into exhaust region 309 and out pump-out valve 312. In one embodiment, exhaust regions 310 and 309 may be controlled relative to volume to exist having minimal volume just under reactive region 314. In another embodiment, direct porting may be implemented between openings 306 and 307 and respective pump-out valves 311 and 312 respectively. It is noted herein as well that there may be more than two separate exhaust regions implemented without departing from the spirit and scope of the present invention. Likewise, there may be more than two openings in plate 303 a portion of which may be dedicated to a specific exhaust region.

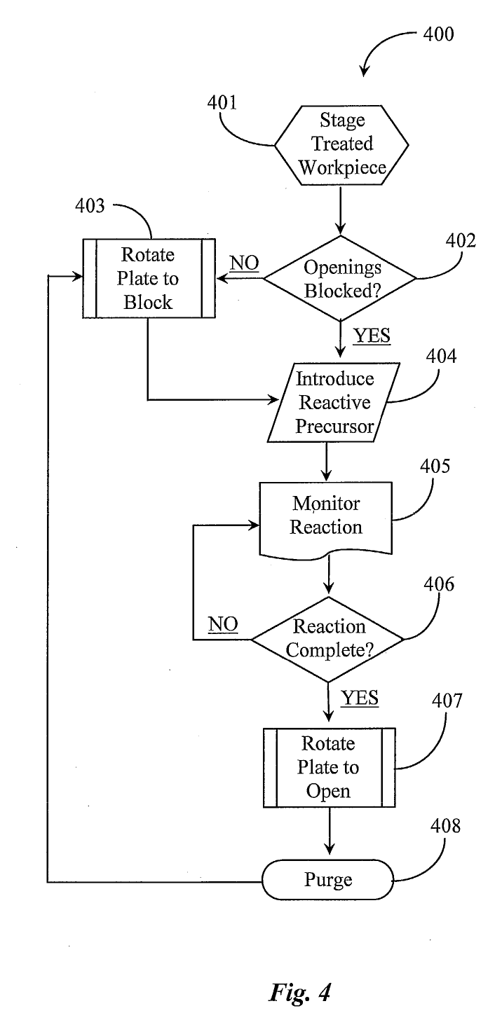

FIG. 4 is a process flow chart illustrating acts 400 for purging reactants into a single exhaust region according to an embodiment of the present invention. At act 401 a treated workpiece is staged for cycling. In some processes, staging a workpiece is automatic. In other processes, a user performs workpiece staging manually.

At act 402, a determination is made regarding the plate valve state, for example whether the openings are blocked for dosing or open to create one or more pathways for purging. In most processes that repeat, the plate valve will automatically be closed by default at the beginning of a process. If at act 402 it is determined that the openings are open, in other words, the plates are aligned for purge, then at act 403, the rotably adjustable plate of the pair comprising the plate valve is rotated to block the openings for the dosing portion of the sequence. The process then resolves to act 404 wherein the reactive precursor is introduced into the reactive region. If at act 402 it is determined that the openings are blocked then the process moves directly to act 404.

At act 404 a reactive gas is introduced that reacts with the treated surface of the workpiece to produce a layer of thin film covering the exposed or un-masked areas of the workpiece. It is assumed that the reaction takes place in act 404 as the gas is introduced in a pulse. At act 405 the reaction may be monitored for progress. Act 405 may simply be a time period in which the reaction is expected to occur and culminate in the thin film layer. In one embodiment however, instrumentation may be provided for measuring the reaction and the results of that reaction. In another embodiment the change in position of the rotating plate itself is used to control the introduction of reactive gas and purge gas.

At act 406, it is determined whether the reaction has completed. If it has, then the rotably adjustable plate is rotated to align the openings in both plates to create a pathway for purging what is left of the reactive gas. If at act 406 it is determined that the reaction is not complete then the process resolves back to act 405 for monitoring. An affirmative at act 406 may be just an indication of the end of the planned reaction time window. Act 407 may involve a total alignment of the openings or a partial alignment of the openings depending on the design of the process. Likewise, the openings may be holes, slots, or openings of varied shapes and sizes without departing from the spirit and scope of the present invention.

At act 408, a purge step is performed to pump-out any residue in the reactive region into an exhaust region. Although not illustrated in this process flow, act 408 may involve introduction of an inert gas into the reactive region just before pump-out. During purge in act 408 very high flows are created at very low pressure. In one embodiment, there may be a sub-act associated with act 408 for monitoring the purge and determining when the purge act is complete. In one embodiment, a pre-planned time window is provided wherein the expected results of the purge should be accomplished. Therefore, the determination that the purge is complete may be just an indication of the end of the purge cycle in time. After act 408 is complete in any case, the process resolves back to act 403 wherein the rotably adjustable plate is rotated again to block the openings in the plates. At act 404 a next precursor may be introduced and the process continues until the workpiece is finished.

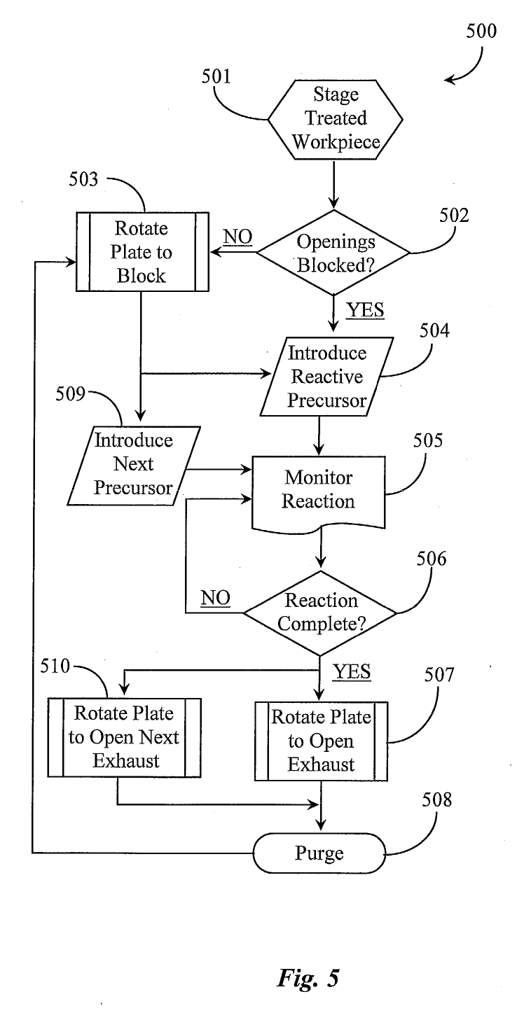

FIG. 5 is a process flow chart illustrating acts 500 for purging reactants into alternate exhaust regions according to an embodiment of the present invention. At act 501, a treated workpiece is staged for processing as described above. At act 502, a determination may be made as to the rotational position of the plates indicating alignment or blockage of the openings. If at act 502, the openings are not blocked then the process resolves to act 503 wherein the rotably adjustable plate is rotated to block the opening or openings for the dose portion of the cycle. If at act 502 it is determined that the openings are blocked, then the process moves directly to act 504 wherein a reactive precursor is introduced into the reactive region. If the rotably adjustable plate has to be rotated to block the openings in act 503, the process resolves to act 504 just described.

At act 505, the reaction resulting from the introduction of the precursor in act 504 may be monitored to determine results of the reaction and whether the reaction is complete. The monitoring may be active monitoring or just an indication of the end of a pre-planned time period in which the reaction is expected to take place and to complete. At act 506 a determination is made if the reaction is complete. If not, then the process resolves back to act 505. If the reaction has completed in act 506, then at act 507 the adjustable plate is rotated to open or align two or more openings to a specific exhaust region. This is where the process differs from the process explained in the description of FIG. 4. That is to say that in this example, a specific exhaust region of more than one region is dedicated to pumping out the precursor introduced in act 504. Therefore, only a specific alignment has to be performed with respect to the rotably adjustable plate of the valve opening only the pathway or pathways dedicated to that exhaust region.

At act 508, a purge process is performed, which may include a sub act for introduction of an inert gas and a sub act for monitoring. After the purge is complete into the designated exhaust region, the process resolves back to act 503 in which the rotably adjustable plate is rotated again to block all openings.

The process then moves to act 509 wherein a next reactive precursor, different from the precursor of act 504, is introduced. The process then moves back to act 505 for monitoring and act 506 to determine if the reaction resulting from the gas introduction of act 509 is complete. It is noted herein that the cycle times may be different for different chemistries. If at act 506, the next reaction is not complete, the process may loop back to monitoring at act 505. If the reaction is determined to be complete at act 506, then at act 510, the rotably adjustable plate is rotated to align the opening or openings dedicated as passages into the next exhaust region. During this phase, the initial exhaust region and any other regions are blocked.

The process then moves back to act 508 for purging, which may include a sub-act for monitoring and a sub act for introducing an inert gas into the reactive region as previously described. After the purge act 508, the process moves back to act 503 wherein the rotably adjustable plate is again rotated to block all openings in preparation for a dosing involving the next precursor introduction.

One with skill in the art will appreciate that use of different chemistries may alter the process somewhat without departing from the spirit and scope of the invention. Likewise, there may be fewer or more acts including sub-acts implemented in acts 400 or in acts 500 depending on the exact process design followed. Generally speaking the acts of rotably adjusting the plate valve according to its design and purpose, whether designed with one exhaust region or more than one exhaust region represents an improved process over those requiring linear displacement of large vacuum plates or lids.

In one embodiment, there may be sensors provided that indicate the actual positioning of the adjustable valve in order to control the actuation of gas introduction valves used for reactant and purge gas injection relative to dose and purge acts of this process. In this embodiment, provision of such motion or “travel” sensors allows the motion of the adjustable valve to be either continuous at variable speed, or in discrete steps, always with correct timing of reactant introduction and routing of each reactant to its own separated exhaust region with minimal undesired mixing.

Although the embodiments and processes described herein are targeted chiefly for ALD processing, it will be clear to one with skill in the art that advantages provided by the invention may also apply to many CVD processes as well. Likewise, other shapes of valve components may be envisioned and implemented without departing from the spirit and scope of the present invention. Such alternatives to rotably adjustable plates include a spherical component pair or a cylindrical component pair where one of the components is adjustable to align or misalign perforations or openings common to both components of the pair.

In still another alternative embodiment, two linear moveable valve plates may be provided, each having two or more openings that may be aligned to form pathways or blocked to prevent pathways using linear displacement of one of the plates. While less effective than rotation for reducing cycle time, such an apparatus would be more effective that a single heavy vacuum plate or lid. Therefore the methods and apparatus of the invention as described herein should be afforded the broadest possible scope under examination. The spirit and scope of the present invention should be limited only by the following claims.

What is claimed is:

1. A pumping apparatus for evacuating a reactant from a reactive region comprising:
a vacuum able chamber;
a hearth for supporting a workpiece;
one or more gas introduction valves;
one or more exhaust evacuation valves; and
an adjustable valve providing one or more pathways there through formed by alignment of separate components of the valve, the components perforated with two or more openings to form the pathways.

2. The pumping apparatus of claim 1, wherein the apparatus is used in atomic layer deposition.

3. The pumping apparatus of claim 1, wherein the apparatus is used in chemical vapor deposition.

4. The pumping apparatus of claim 1, wherein the components are annular plates arranged one above the other and wherein one of those plates may be rotated to form or to block the pathways.

5. The pumping apparatus of claim 4, wherein the plate that is not rotated is permanently affixed to the chamber and to the hearth.

6. The pumping apparatus of claim 4, wherein magnetic coupling from outside the chamber controls the rotably adjustable plate.

7. The pumping apparatus of claim 4, wherein a centrally located spindle controls the rotably adjustable plate.

8. The pumping apparatus of claim 1, wherein the chamber includes one reactive region located above the adjustable valve, and one exhaust region located below the adjustable valve.

9. The pumping apparatus of claim 1, wherein the chamber includes one reactive region located above the adjustable valve, and two or more isolated exhaust regions located below the adjustable valve, the exhaust regions isolated from one another by the rotated position of the rotably adjustable plate of the valve.

10. The pumping apparatus of claim 7, wherein the spindle is magnetically coupled to the rotably adjustable plate.

11. The pumping apparatus of claim 7, wherein the spindle is physically attached to the rotably adjustable plate.

12. An adjustable valve for evacuating a reactive precursor from a reactive region in a semiconductor thin film process chamber comprising:
a first perforated component rendered stationary within the process chamber; and
a second perforated component geometrically similar to the first perforated component, the second perforated component rotable within the chamber to align one or more of the perforations common to both components to form one or more pathways through the valve and rotable within the chamber to misalign all of the perforations common to both components to prevent pathways through the valve.

13. The adjustable valve of claim 12, wherein the semiconductor thin film process is an atomic layer deposition process.

14. The adjustable valve of claim 12, wherein the first and second perforated components are annular plates.

15. The adjustable valve of claim 12, wherein the second perforated component is adjustable using magnetic coupling.

16. The adjustable valve of claim 12, wherein the first perforated component is contiguously formed with the process chamber.

17. The adjustable valve of claim 12, wherein both perforated components have identical perforations strategically located in identical patterns.

18. A method for purging a reactant from a reactive region of a semiconductor thin film process using an adjustable valve adjacent to the reactive region, the valve including a first perforated component rendered stationary within a process chamber, and an adjustable second perforated component geometrically similar to the first perforated component comprising the acts:
(a) determining that a reaction has occurred in the reactive region; and
(b) adjusting the second perforated component to align one or more perforations common to both perforated components, the adjustment performed under vacuum pressure.

19. The method of claim 18, wherein in act (a), the determination is made according to the passing of a pre-planned time window in which the reaction is expected to have occurred and completed.

20. The method of claim 18, wherein in act (b), the perforated components are annular plates and the adjustment is a rotation of one of the plates.

21. The method of claim 18 wherein in act (a), sensors indicating the actual position of the adjustable valve are provided and control the actuation of gas introduction valves used for reactant and purge gas injection in act (b).
